(19) United States
(12) Patent Application Publication
(10) Pub. No.: US 2013/0089680 A1
(43) Pub. Date: Apr. 11, 2013

(54) PLASMA-ENHANCED DEPOSITION OF RUTHENIUM-CONTAINING FILMS FOR VARIOUS APPLICATIONS USING AMIDINATE RUTHENIUM PRECURSORS

(71) Applicants: Christian DUSSARRAT, Wilmington, DE (US); Vincent M. OMARJEE, Grenable (FR); Clement LANSALOT-MATRAS, Tsukuba (JP)

(72) Inventors: Christian DUSSARRAT, Wilmington, DE (US); Vincent M. OMARJEE, Grenable (FR); Clement LANSALOT-MATRAS, Tsukuba (JP)

(73) Assignee: American Air Liquide, Inc., Fremont, CA (US)

(21) Appl. No.: 13/269,151

(22) Filed: Oct. 7, 2011

(51) Int. Cl. C23C 16/18; C23C 16/50

(52) U.S. Cl. 427/576

(57) ABSTRACT

The present invention relates to a process for the use of Ruthenium amidinate metal precursors for the deposition of Ruthenium-containing films via Plasma Enhanced Atomic Layer Deposition (PEALD) or Plasma Enhanced Chemical Vapor Deposition (PECVD).

### TECHNICAL FIELD

The present invention relates to a process for the use of metal amidinate metal precursors for the deposition of metal containing film via Plasma Enhanced Atomic Layer Deposition (PEALD) or Plasma Enhanced Chemical Vapor Deposition (PECVD).

### BACKGROUND ART

Ruthenium is a metal that is attracting a lot of attention in semiconductor industry. Despite its relative expensiveness, this metal is proven to have many advantages that justify its use.

Pure Ruthenium metal was studied to be used as metal electrode in advance transistor applications. In BEOL, Ruthenium can be used to improve the Copper wettability and direct platting on Ru and RuTaN is also possible. It can be also used as a glue layer between tungsten and dielectrics materials.

In some new applications, SrRuOx (SRO) is also a material of interest. For memory for instance, SRO was found to have a good lattice matching with STO (SrTiOx—an ultra high dielectric constant material that is intended to be used in the coming DRAM new generations). In more exotic applications, SRO is of interest for FeRAM to enhance the fatigue property of lead zirconate titanate (PZT) films.

As Cu interconnect feature sizes shrink, current density is increasing, creating greater risk of electromigration (EM) failure. One cause of the EM failure is related to the interface between Cu and dielectric capping layers. One way to reduce EM is to use a metal capping layer with Ru capping being one proven material.

Ruthenium also plays an important role in the data storage industry more specifically for Giant Magnetoresistance (“GMR”) where a Ru thin layer is used in the reading head.

Many Ru precursors are available and many have been studied in for thin film vapor deposition; however the currently available precursors have some drawbacks such as low vapor pressure (only 0.1 Torr at 73° C. for Ru(EtCp)₂) and high impurity content in the resulting films (carbon and oxygen contamination in most cases). These impurities will be detrimental to the film resistivity and can contaminate the subsequent deposited layers (oxidation of an adjacent copper layer for instance).

Ru(EtCp)2 was used in ALD by Kwon et al (Kwon et al., J. Electrochem. Soc., Volume 151, Issue 2, pp. G109-G112 (2004)). Some carbon and oxygen were present into the deposited film (<2%). The oxygen is derived from 02 used for the reaction. In BEOL, use of O2 is likely to be difficult since it can cause damaging oxidation of the low-k underlayer film for instance (low-k organosilica glass, Ti N, or Ta/TaN).

Ru precursors, such as tricarbonyl(1,3-cyclohexadiene)Ru, have been used to deposit ruthenium film (Lazarz et al., Mater. Res. Soc. Symp. Proc. Vol. 990, 2007). However, Ru(CO)3(1,3-cyclohexadiene) is not liquid at room temperature (it melts at about 35° C.) and it is necessary to dissolve this precursor in a solvent in order to obtain a liquid solution of precursor and solvent through which an inert carrier gas such as helium is bubbled. Also, the tricarbonyl component can contaminate the film with C and/or O residues. The carbon monoxide derived from the tricarbonyl group is additionally a safety problem that may require specific safety measures.

Another standard precursor, RuO₄, as been extensively studied and can allow deposition of good quality film by CVD. However, no ALD regime is available.

Wang et al. (Chem. Vap. Deposition 2009, 15, 312-319) used a Ruthenium amidinate precursor in thermal ALD (bis(N,N′-di-tert-butylacetamidinato)ruthenium(II) dicarbonyl and O2).

Ruthenium tris amidinate can be prepared according to the published method in The Open Inorganic Chemistry Journal, 2008, 2, 11-17 by reacting RuCl3(Me2S)3 with tree equivalents of the corresponding lithium amidinate.

### DISCLOSURE OF INVENTION

The invention may be defined in part by the following paragraphs [0014]-[00027]:
A method for depositing a Ruthenium-containing film comprising the step of providing a Ruthenium guanidinate and/or Ruthenium or amidinate precursor, suitable for plasma deposition at temperature equal or lower than 300 degrees C., to a plasma deposition process comprising a deposition temperature equal or lower than 300 degrees C.
The method of paragraph [00014], wherein the deposition temperature is at a temperature of 20-300 degrees C.
The method of paragraph [00014], wherein the deposition temperature is at a temperature of 150-300 degrees C.
The method of any one of paragraphs [00014]-[00016], wherein the Ru containing film is deposited on a substrate coated with one or more of Ru, Mn, Low-k, Ta, TaN, SiO₂.
The method of any one of paragraphs [00014]-[00016], further comprising at least a step of providing one co-reactant amine or reducing agent to the plasma deposition process.
The method of any one of paragraphs [00014]-[00016] or any one of paragraphs [00014]-[00016] in combination with one or both of paragraphs [00017] or [00018], further comprising a step of providing one or more of O₂, O₃, H₂O, H₂O₂, NO, NO₂, or a carboxylic acid to the plasma deposition process.

The method of any one of paragraphs [00014]-[00016] or any one of paragraphs [00014]-[00016] in combination with one or more of paragraphs [00017]-[00019], wherein the plasma deposition process is a PECVD process.

The method of paragraph [00018], wherein the plasma deposition process is a PEALD process comprising a plurality of cycle.

The method of any one of paragraphs [00014]-[00016] or any one of paragraphs [00014]-[00016] in combination with one or more of paragraphs [00017]-[00021], wherein the Ru film is a substantially pure Ru.

The method of any one of paragraphs [00014]-[00016] or any one of paragraphs [00014]-[00016] in combination with one or more of paragraphs [00017]-[00022], wherein the suitable Ru precursor has the structure of compound (III)

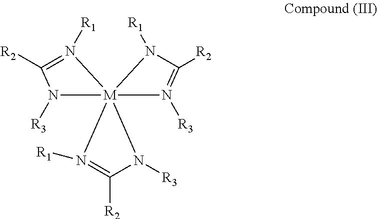

wherein:
M is Ru; and
R₁ and R₃ are independently selected from H, a C1-05 alkyl group, and Si(R′)₃, where R′ is independently selected from H, and a C1-C5 alkyl group. R₂ is independently selected from H, a C1-C5 alkyl group, and NR′R″, where R′ and R″ are independently selected from C1-C5 alkyl groups.
The method of one of paragraphs [00014]-[00016] or any one of paragraphs [00014]-[00016] in combination with one or more of paragraphs [00017]-[00022] wherein the Ru precursor is tris(N,N′-diisopropylpentylamidinato)ruthenium.

The present invention relates to a process for the use of Ruthenium amidinate metal precursors for the deposition of Ruthenium-containing films via

Plasma Enhanced Atomic Layer Deposition (PEALD) or Plasma Enhanced Chemical Vapor Deposition (PECVD). Plasma improves deposition rates and/or film properties at deposition temperatures below 300 degrees C. The identification of plasma compatible Ruthenium amidinate precursors permits the application of plasma to Ruthenium depositions to derive the benefits of PECVD or PEALD and achieve acceptable deposition rates and film properties at the industrially required temperatures.

In some embodiments, the present invention provides methods of depositing pure Ruthenium film by plasma enhanced atomic layer deposition (PEALD) and plasma enhanced chemical vapor deposition (PECVD). “Pure Ruthenium” is defined as at least 90% Ruthenium such as 95% or more Ruthenium, 99% or more Ruthenium or 99.9% or more Ruthenium.

In some embodiments of the invention, Ruthenium amidinate or

Ruthenium guanidinate is used at deposition temperatures lower than 300 degrees C. to form Ruthenium films.

In some embodiments, the Ruthenium deposition method includes the steps of providing a substrate; providing a vapor of a Ruthenium guanidinate or a Ruthenium amidinate precursor; and contacting the vapor including the at least one Ruthenium precursor with the substrate (and typically directing the vapor to the substrate) to form a Ruthenium-containing layer on at least one surface of the substrate at temperature of 300 degrees C. or lower.

In some embodiments, the substrate is coated with a surface diffusion or barrier layer. Examples of diffusion layers or glue layers are without limitation TaN, Ta, SiO2, Si, low-k, Mn or any combination thereof.

In one embodiment of the invention, the preferred Ruthenium precursor is represented by compound (III)

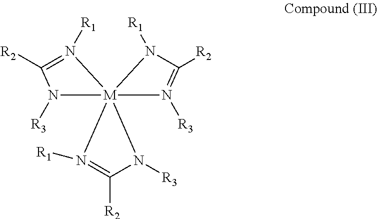

wherein M is Ru; and

R₁ and R₃ are independently selected from H, a C1-C5 alkyl group, and Si(R′)₃, where R′ is independently selected from H, and a C1-C5 alkyl group. R₂ is independently selected from H, a C1-C5 alkyl group, and NR′R″, where R′ and R″ are independently selected from C1-C5 alkyl groups.

An exemplary species of Ruthenium precursor is tris(N,N′-diisopropylpentylamidinato)ruthenium.

Deposition conditions for the invention include temperatures at or below 300 degrees C. preferably in the range of 20-300 degrees C.

Deposition conditions for the invention may also include pressures ranging from 0.5 mTorr to 20 Torr to deposit films having the general formula M, MₖSiₗ, MₙOₘ or MₓN_{y}O_{z}. Film composition will be dependent on the application. Where k, l, m, n, x, y range from 1 to 6, inclusive.

The deposition may include one or more co-reactants such as an amine containing reactant or a reducing agent. Exemplary co-reactants are H₂, NH₃, dimethylsilane, diethylsilane, BuNH₂, B₂H₆, GeH₄, SnH₄, AlH₃, or an alkyl silane containing a Si—H bond.

The deposition may include one or more co-reactant oxygen sources preferably O₂, O₃, H₂O, H₂O₂, NO, NO₂, a carboxylic acid,

The Ruthenium precursor may be delivered in neat form or in a blend with a suitable solvent, preferably Ethyl benzene, Xylenes, Mesitylene, Decane, or Dodecane in suitable concentrations.

In some embodiments, preferred applications but not limited to could be Ruthenium deposition on silicon, metal deposition on Ta, TaN or WN to ultimately form metal layer, metal oxide deposition for ReRAM applications.

It will be understood that many additional changes in the details, materials, steps, and arrangement of parts, which have been herein described and illustrated in order to explain the nature of the invention, may be made by those skilled in the art within the principle and scope of the invention as expressed in the appended claims. Thus, the present invention is not intended to be limited to the specific embodiments in the examples given above and/or the attached drawings.

What is claimed is:

1. A method for depositing a Ruthenium-containing film comprising the step of providing a Ruthenium guanidinate and/or Ruthenium amidinate precursor, suitable for plasma deposition at temperature equal or lower than 300 degrees C., to a plasma deposition process comprising a deposition temperature equal or lower than 300 degrees C.

2. The method of claim 1, wherein the deposition temperature is at a temperature of 20-300 degrees C.

3. The method of claim 1, wherein the deposition temperature is at a temperature of 150-300 degrees C.

4. The method of claim 1, wherein the Ru containing film is deposited on a substrate coated with one or more of Ru, Mn, Low-k, Ta, TaN, or SiO₂.

5. The method of claim 1, comprising a step of providing at least one co-reactant amine or reducing agent to the plasma deposition process.

6. The method of claim 1, further comprising a step of providing to the plasma deposition process one or more of O₂, O₃, H₂O, H₂O₂, NO, NO₂, or a carboxylic acid.

7. The method of claim 1, wherein the plasma deposition process is a PECVD process.

8. The method of claim 7, wherein the plasma deposition process is a PEALD process comprising a plurality of cycle.

9. The method of claim 1, wherein the Ru film is a substantially pure Ru.

10. The method of claim 1, wherein the film is a Ru containing film and the suitable Ru precursor has the structure of compound (III) 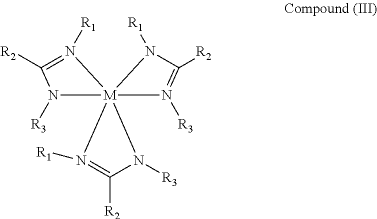
wherein:
M is Ru; and
R₁ and R₃ are independently selected from H, a C1-C5 alkyl group, and Si(R)₃, where R′ is independently selected from H, and a C1-C5 alkyl group. R₂ is independently selected from H, a C1-C5 alkyl group, and NR′R″, where R′ and R″ are independently selected from C1-C5 alkyl groups.

11. The method of claim 12, where the Ru precursor is tris(N,N′-diisopropylpentylamidinato)ruthenium.
